(19) United States
(12) Patent Application Publication
(10) Pub. No.: US 2026/0310066 A1
(43) Pub. Date: Oct. 8, 2026

(54) REFLECTIVE MASK BLANK, REFLECTIVE MASK, REFLECTIVE MASK BLANK PRODUCING METHOD, AND REFLECTIVE MASK PRODUCING METHOD

(71) Applicant: AGC INC., Tokyo (JP)

(72) Inventors: Masahiko TAMURA, Tokyo (JP); Daisuke YOSHIMUNE, Koriyama-shi (JP)

(73) Assignee: AGC INC., Tokyo (JP)

(21) Appl. No.: 19/681,695

(22) Filed: May 19, 2026

Related U.S. Application Data
(63) Continuation of application No. PCT/JP2024/040976, filed on Nov. 19, 2024.

(30) Foreign Application Priority Data
Dec. 5, 2023 (JP) 2023-205053
Feb. 9, 2024 (JP) 2024-018396

(51) Int. Cl. G03F 1/48; G03F 1/24; G03F 1/54; G03F 1/82

(52) U.S. Cl. CPC G03F 1/48; G03F 1/24; G03F 1/54; G03F 1/82

(57) ABSTRACT

An object of the present invention is to provide a technology that solves the problem of difficulty in correcting the position of an opening pattern formed in an absorbing film when defects that are present between a substrate and the absorbing film are clustered, and improves the success probability for the position correction of the opening pattern formed in the absorbing film. A reflective mask blank in which a protective film and an absorbing film are formed on a multilayer reflective film has a quality assurance area that coincides with an exposure area in a plan view, and the quality assurance area is configured so that, after the formation of the protective film and before the formation of the absorbing film, the number of first defects detectable by EUV light and having a sphere equivalent diameter of 14 nm or greater is 1 or less in any inspection area having a square shape with each side length of 20 mm.

This application is a continuation of International Application No. PCT/JP2024/040976, filed on Nov. 19, 2024, which claims the benefit of priority to Japanese Application No. 2023-205053, filed Dec. 5, 2023, and Japanese Application No. 2024-018396, filed Feb. 9, 2024; the disclosure of each of these applications are each incorporated herein by reference in their entirety.

### TECHNICAL FIELD

The present disclosure relates to a reflective mask blank, a reflective mask, a method for producing a reflective mask blank, and a method for producing a reflective mask.

### BACKGROUND ART

In recent years, with the miniaturization of semiconductor devices, EUV lithography (EUVL), an exposure technology using extreme ultraviolet (EUV) radiation, has been developed. EUV has a wavelength of approximately 13.5 nm. A reflective mask is used in EUVL. A reflective mask has, in this order, a substrate such as a glass substrate, a multilayer reflective film that reflects EUV light, a protective film that protects the multilayer reflective film, and an absorbing film that absorbs EUV light. The absorbing film may not only absorb EUV light but also shift the phase of the EUV light. In other words, the absorbing film may be a phase shift film. An opening pattern is formed in the absorbing film. In EUVL, the opening pattern in the absorbing film is transferred to a target substrate such as a semiconductor substrate. The transferring includes reducing and transferring.

Patent Document 1 describes a method for inspecting a substrate with a multilayer reflective film. This inspection method detects and stores the position of defects. This allows the position of the opening pattern formed in the absorbing film to be corrected so that the defects are covered by the absorbing film. As a result, the defects can be made not to adversely affect the EUVL transfer accuracy. This technique is called mitigation.

### CITATION LIST

### Patent Document

Patent Document 1: Japanese Unexamined Patent Application, First Publication No. 2022-165217

### SUMMARY OF INVENTION

### Technical Problem

Conventionally, defects present between the substrate and the absorbing film are clustered, making it difficult to correct the position of the opening pattern formed in the absorbing film.

One embodiment of the present disclosure provides a technology for improving the success probability for the position correction of an opening pattern to be formed in an absorbing film.

### Solution to Problem

A reflective mask blank according to one embodiment of the present disclosure includes, in this order, a substrate, a multilayer reflective film that reflects EUV light, a protective film that protects the aforementioned multilayer reflective film, and an absorbing film that absorbs EUV light, and the aforementioned absorbing film has an exposure area that is scheduled to be exposed to EUV light by an exposure device. The aforementioned protective film has a quality assurance area that coincides with the aforementioned exposure area in a plan view. After the formation of the aforementioned protective film and before the formation of the aforementioned absorbing film, in the aforementioned quality assurance area, the number of first defects detectable by EUV light and having a sphere equivalent diameter of 14 nm or greater is 1 or less in any inspection area having a square shape with each side length of 20 mm.

### Advantageous Effects of Invention

According to one embodiment of the present disclosure the success probability for the position correction of an opening pattern to be formed in an absorbing film can be improved.

### BRIEF DESCRIPTION OF DRAWINGS

FIG. 1 is a cross sectional view showing a reflective mask blank according to one embodiment.

FIG. 2 is a flowchart showing a method for producing a reflective mask blank according to one embodiment.

FIG. 3 is a cross sectional view showing a reflective mask according to one embodiment.

FIG. 4 is a flowchart showing a method for producing a reflective mask according to one embodiment.

FIG. 5(A) is a cross sectional view showing an example of S201, FIG. 5(B) is a cross sectional view showing an example of S202, and FIG. 5(C) is a cross sectional view showing an example of S203.

FIG. 6 is a cross sectional view showing an example of EUV light reflected by the reflective mask in FIG. 3.

FIG. 7 is a cross sectional view showing an example of the positional relationship between an opening pattern in an absorbing film and defects.

FIG. 8 is a diagram showing an example of the relationship between a set of defects detectable by EUV light and a set of defects detectable by DUV light.

FIG. 9 is a diagram showing an example of a spin cleaning device.

FIG. 10 is a plan view showing a first example of the positional relationship among a quality assurance area, an inspection area, a first defect DA, and a second defect DB.

FIG. 11 is a plan view showing a second example of the positional relationship between the quality assurance area, inspection area, first defect DA, and second defect DB.

FIG. 12 is a plan view showing a third example of the positional relationship between the quality assurance area, inspection area, first defect DA, and second defect DB.

### DESCRIPTION OF EMBODIMENTS

Embodiments for carrying out the present disclosure will be described below with reference to the drawings. Identical or corresponding configurations in each drawing are designated by the same reference numerals, and their descriptions may be omitted. In the specification, a symbol “-” indicating a numerical range means that numerical values described before and after this symbol are included as the lower limit value and the upper limit value. The numerical range includes a rounded range.

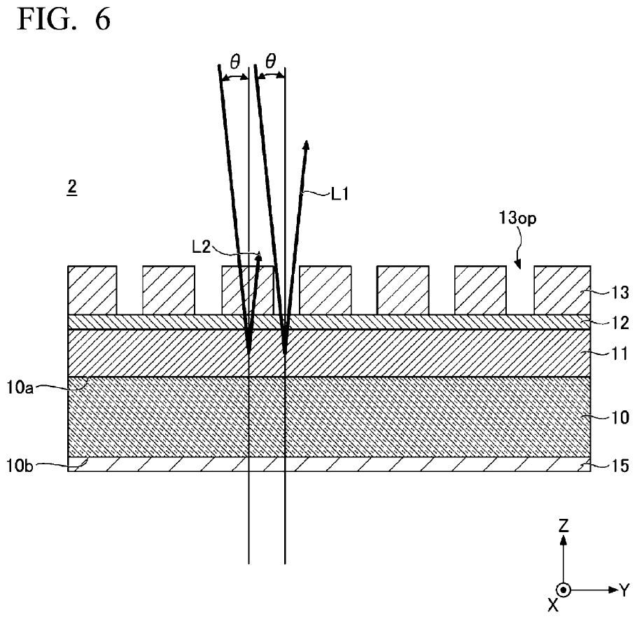

In each drawing, the X-axis direction, Y-axis direction, and Z-axis direction are directions perpendicular to one another. The Z-axis direction is a direction perpendicular to a first main surface 10a of a substrate 10. The X-axis direction is a direction orthogonal to a plane of incidence of the EUV light (a plane containing the incident ray and reflected rays). As shown in FIG. 6, the incident rays are tilted in the positive Y-axis direction as they travel toward the negative Z-axis direction, and the reflected rays are tilted in the positive Y-axis direction as they travel toward the positive Z-axis direction.

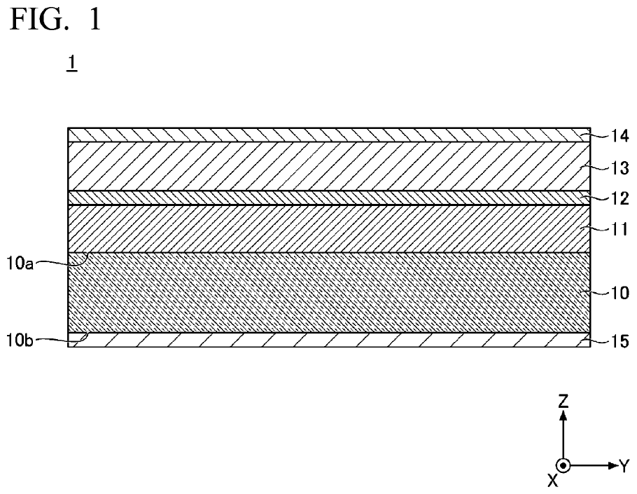

With reference to FIG. 1, a reflective mask blank 1 according to one embodiment will be described. The reflective mask blank 1 includes, for example, the substrate 10, a multilayer reflective film 11, a protective film 12, an absorbing film 13, and a hard mask film 14, in this order. The multilayer reflective film 11, the protective film 12, the absorbing film 13, and the hard mask film 14 are formed, in this order, on the first main surface 10a of the substrate 10. The multilayer reflective film 11 reflects EUV light. The protective film 12 protects the multilayer reflective film 11 from a first etching gas during processing of the absorbing film 13. The absorbing film 13 absorbs EUV light. The absorbing film 13 may not only absorb EUV light but also shift the phase of the EUV light. In other words, the absorbing film 13 may be a phase shift film. The hard mask film 14 protects a portion of the absorbing film 13 from the first etching gas during processing of the absorbing film 13.

The reflective mask blank 1 has a conductive film 15 on the opposite side of the multilayer reflective film 11, with reference to the substrate 10. In other words, the reflective mask blank 1 may have the conductive film 15, the substrate 10, the multilayer reflective film 11, the protective film 12, the absorbing film 13, and the hard mask film 14, in this order. The conductive film 15 is formed on a second main surface 10b of the substrate 10. The second main surface 10b is a surface facing the opposite from the first main surface 10a. The conductive film 15 is used to adsorb a reflective mask 2 to an electrostatic chuck of an exposure device.

The reflective mask blank 1 may further include a functional film not shown in FIG. 1. For example, the reflective mask blank 1 may include an anti-reflection film (not shown) between the absorbing film 13 and the hard mask film 14. The anti-reflection film improves optical contrast during inspection of an opening pattern 13op of the absorbing film 13. In addition, the reflective mask blank 1 may include a diffusion barrier film (not shown) between the multilayer reflective film 11 and the protective film 12. The diffusion barrier film suppresses metal elements contained in the protective film 12 from diffusing into the multilayer reflective film 11.

The reflective mask blank 1 may also include a buffer film (not shown) between the protective film 12 and the absorbing film 13.

The buffer film protects the protective film 12 from the first etching gas that forms the opening pattern 13op in the absorbing film 13. The buffer film is etched more slowly than the absorbing film 13. Unlike the protective film 12, the buffer film ultimately has an opening pattern identical to the opening pattern 13op in the absorbing film 13.

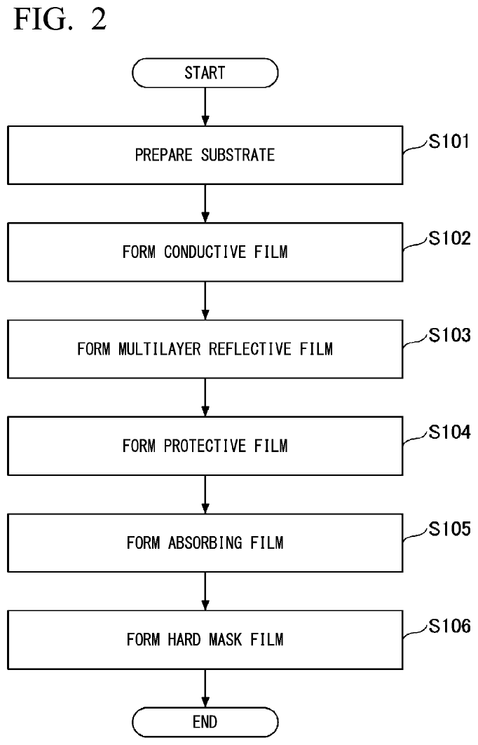

Next, with reference to FIG. 2, a method for producing the reflective mask blank 1 according to one embodiment will be described. The method for producing the reflective mask blank 1 includes, for example, steps S101 to S106 shown in FIG. 2. In step S101, the substrate 10 is prepared. In step S102, the conductive film 15 is formed on the second main surface 10b of the substrate 10. In step S103, the multilayer reflective film 11 is formed on the first main surface 10a of the substrate 10. In step S104, the protective film 12 is formed on the multilayer reflective film 11. In step S105, the absorbing film 13 is formed on the protective film 12. In step S106, the hard mask film 14 is formed on the absorbing film 13.

It should be noted that the order of steps S101 to S106 is not limited to that shown in FIG. 2. For example, the order of step S102 and steps S103 to S106 may be reversed. Further, the method for producing the reflective mask blank 1 may not include all of steps S101 to S106. The method for producing the reflective mask blank 1 may further include a step of forming a functional film (not shown in FIG. 2).

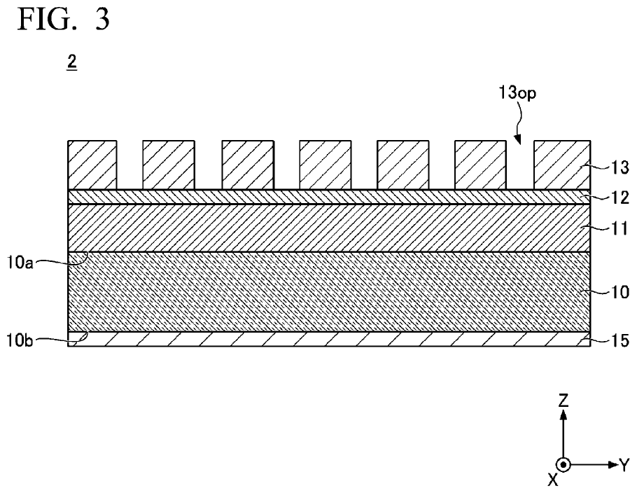

Next, with reference to FIG. 3, a reflective mask 2 according to one embodiment will be described. The reflective mask 2 is provided with, for example, the reflective mask blank 1 shown in FIG. 1 and includes the opening pattern 13op in the absorbing film 13. In EUVL, the opening pattern 13op in the absorbing film 13 is transferred to a target substrate such as a semiconductor substrate. The transferring includes reducing and transferring. It should be noted that the hard mask film 14 shown in FIG. 1 is not included in the reflective mask 2.

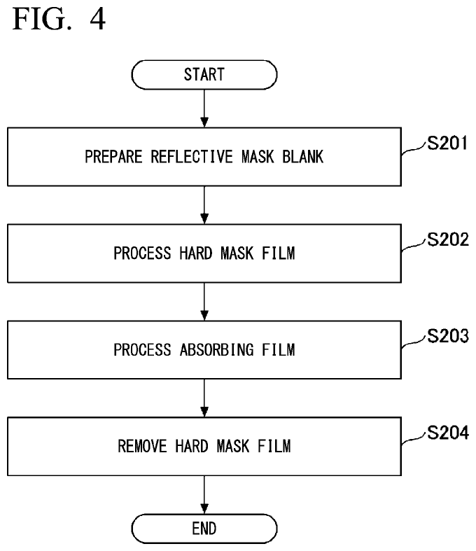

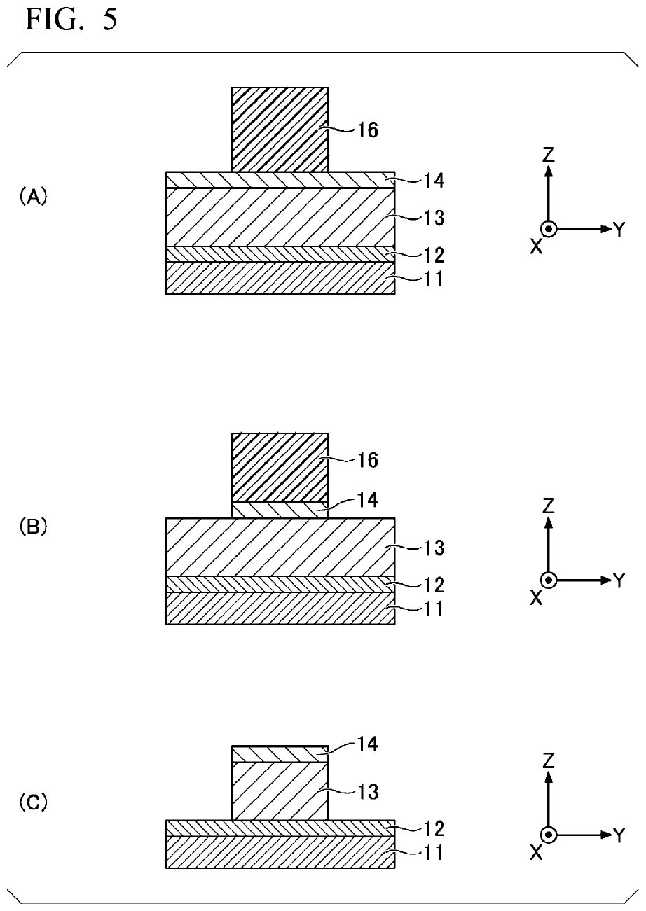

Next, with reference to FIGS. 4 and 5, a method for producing the reflective mask 2 according to one embodiment will be described. The method for producing the reflective mask 2 includes steps S201 to S204 shown in FIG. 4. In step S201, the reflective mask blank 1 is prepared, as shown in FIG. 5(A). The reflective mask blank 1 includes a resist film 16, as shown in FIG. 5(A). The resist film 16 is formed on the hard mask film 14. The resist film 16 has an opening pattern formed therein that is scheduled to be transferred to the absorbing film 13.

In step S202, as shown in FIG. 5(B), the hard mask film 14 is processed using the resist film 16 having an opening pattern. The hard mask film 14 is exposed to a second etching gas in the openings in the resist film 16, and the second etching gas etches the hard mask film 14. At the end of step S202, the resist film 16 remains. As a result, the opening pattern of the resist film 16 is transferred to the hard mask film 14.

The second etching gas is selected in accordance with the combination of the material of the resist film 16 and the material of the hard mask film 14, and is not particularly limited, but contains, for example, a fluorine-based gas. The fluorine-based gas contains, for example, at least one selected from the group consisting of CF₄ gas, CHF₃ gas, C₂F₆ gas, C₃F₆ gas, C₄F₆ gas, C₄F₈ gas, CH₂F₂ gas, CH₃F gas, C₃F₈ gas, F₂ gas, SF₆ gas, and NF₃ gas. In addition to the fluorine-based gas, the second etching gas may contain an active gas or an inert gas. The active gas contains, for example, at least one selected from the group consisting of O₂ gas and O₃ gas. The inert gas contains, for example, at least one selected from the group consisting of N₂ gas, He gas, and Ar gas. The second etching gas is preferably in a plasma state.

In step S203, as shown in FIG. 5(C), the absorbing film 13 is processed using the hard mask film 14 having an opening pattern. The absorbing film 13 is exposed to the first etching gas in the openings in the hard mask film 14, and the first etching gas etches the absorbing film 13. The hard mask film 14 exhibits higher resistance to the first etching gas than the absorbing film 13. At the end of step S203, the hard mask film 14 remains. As a result, the opening pattern of the hard mask film 14 is transferred to the absorbing film 13.

The first etching gas is selected in accordance with the combination of the material of the hard mask film 14 and the material of the absorbing film 13, and is not particularly limited, but contains, for example, a chlorine-based gas and an oxygen-based gas. The chlorine-based gas contains, for example, at least one selected from the group consisting of Cl₂ gas, SiCl₄ gas, CHCl₃ gas, CCl₄ gas, and BCl₃ gas. The oxygen-based gas contains, for example, at least one selected from the group consisting of O₂ gas and O₃ gas. The first etching gas may contain an inert gas in addition to a chlorine-based gas and an oxygen-based gas. The inert gas contains, for example, at least one selected from the group consisting of N₂ gas, He gas, and Ar gas. The first etching gas is preferably in a plasma state.

In step S204, although not shown, the hard mask film 14 is removed. For example, a third etching gas is used to remove the hard mask film 14. Like the second etching gas, the third etching gas contains, for example, a fluorine-based gas. The third etching gas is preferably in a plasma state. A drug solution may be used to remove the hard mask film 14.

Next, referring again to FIG. 1, the substrate 10, the multilayer reflective film 11, the protective film 12, the absorbing film 13, the hard mask film 14, and the conductive film 15 will be described in this order.

The substrate 10 is, for example, a glass substrate. The material of the substrate 10 is preferably quartz glass containing TiO₂. Compared to common soda-lime glass, quartz glass has a smaller linear expansion coefficient and exhibits less dimensional change due to temperature changes. Quartz glass may contain 80% to 95% by mass of SiO₂ and 4% to 17% by mass of TiO₂. When the TiO₂ content is from 4% to 17% by mass, the linear expansion coefficient is approximately zero near room temperature, and there is almost no dimensional change near room temperature. Quartz glass may also contain a third component or impurity other than SiO₂ and TiO₂. It should be noted that the material of the substrate 10 may be crystallized glass obtained by precipitating a β-quartz solid solution, silicon, a metal, or the like.

The substrate 10 has a first main surface 10a and a second main surface 10b facing opposite the first main surface 10a. The multilayer reflective film 11 and the like are formed on the first main surface 10a, and the conductive film 15 is formed on the second main surface 10b. The size of the substrate 10 in a plan view (viewed in the Z-axis direction) is, for example, 152 mm vertically and 152 mm horizontally. The vertical and horizontal dimensions may be 152 mm or more. The first main surface 10a has a rectangular quality assurance area. The quality assurance area coincides with the exposure area in a plan view. The exposure area is an area where the exposure device is scheduled to irradiate the absorbing film 13 with EUV light. The size of the quality assurance area is selected appropriately depending on the size of the substrate 10, but for example, the long side length is 132 mm and the short side length is 104 mm. The quality assurance area preferably has a root mean square roughness (Rq) of 0.15 nm or less and a flatness of 100 nm or less. In addition, the quality assurance area preferably does not have a defect that causes a phase defect.

The multilayer reflective film 11 reflects EUV light. The multilayer reflective film 11 is, for example, formed by alternately laminating high refractive index layers and low refractive index layers. The material of the high refractive index layer is, for example, silicon (Si), and the material of the low refractive index layer is, for example, molybdenum (Mo), and a Mo/Si multilayer reflective film is used. It should be noted that Ru/Si multilayer reflective films, Mo/Be multilayer reflective films, Mo compound/Si compound multilayer reflective films, Si/Mo/Ru multilayer reflective films, Si/Mo/Ru/Mo multilayer reflective films, Si/Ru/Mo/Ru multilayer reflective films, Si/Ru/Mo multilayer reflective films, and the like can also be used as the multilayer reflective film 11.

The film thickness of each layer and the number of repeating units of layers that make up the multilayer reflective film 11 can be selected appropriately depending on the material of each layer and the reflectance for EUV light. When the multilayer reflective film 11 is a Mo/Si multilayer reflective film, in order to achieve a reflectance of 60% or more for EUV light with an incident angle θ of 6° (see FIG. 6), it is sufficient to laminate a Mo layer with a film thickness of 2.3±0.1 nm and a Si layer with a film thickness of 4.5±0.1 nm so that the number of repeating units is 30 or more and 60 or less. The multilayer reflective film 11 preferably has a reflectance of 60% or more for EUV light with an incident angle θ of 6°. The reflectance is more preferably 65% or more.

The method for depositing each layer constituting the multilayer reflective film 11 is, for example, a DC sputtering method, a magnetron sputtering method, an ion beam sputtering method, or the like. When forming a Mo/Si multilayer reflective film using an ion beam sputtering method, an example of each deposition condition for the Mo layers and Si layers is as follows.

### <Si Layer Deposition Conditions>

Target: Si target
Sputtering gas: Ar gas
Gas pressure: 1.3×10⁻² Pa to 2.7×10⁻² Pa
Ion accelerating voltage: 300 V to 1,500 V
Deposition rate: 0.030 nm/sec to 0.300 nm/sec
Film thickness of Si layer: 4.5±0.1 nm

### <Mo Layer Deposition Conditions>

Target: Mo target
Sputtering gas: Ar gas
Gas pressure: 1.3×10⁻² Pa to 2.7×10⁻² Pa
Ion accelerating voltage: 300 V to 1,500 V
Deposition rate: 0.030 nm/sec to 0.300 nm/sec
Film thickness of Mo layer: 2.3±0.1 nm

### <Repeating Units of Si Layer and Mo Layer>

Number of repeating units: 30 to 60 (preferably 40 to 50)

The protective film 12 is formed between the multilayer reflective film 11 and the absorbing film 13 and protects the multilayer reflective film 11. The protective film 12 protects the multilayer reflective film 11 from the first etching gas during processing of the absorbing film 13, in other words, in step S203. The protective film 12 is not removed even when exposed to the first etching gas, and remains on the multilayer reflective film 11.

The protective film 12 contains at least one element selected from, for example, Ru, Rh, and Si. The protective film 12 preferably contains ruthenium (Ru) as a main component. As described above, the protective film 12 containing Ru as a main component means that the Ru content in the protective film 12 is 40 at % or more. The Ru content in the protective film 12 is preferably 45 at % or more, and more preferably 50 at % or more. When the protective film 12 contains Ru, it may contain only Ru, or it may also contain a Ru compound. The Ru compound may be a Ru alloy. The Ru alloy contains, in addition to Ru, at least one metal element selected from, for example, Rh, Nb, Mo, Ta, Ir, Pd, Zr, Y, and Ti.

The Ru compound may also contain, in addition to Ru, at least one nonmetallic element selected from N, O, C, and B. While these nonmetallic elements reduce the resistance of the protective film 12 to the first etching gas, they also reduce the crystallinity of the protective film 12, thereby improving the smoothness of the protective film 12. When the Ru compound has a non-crystalline (amorphous) structure or a microcrystalline structure, the X-ray diffraction pattern of the Ru compound does not have a clear peak.

However, it is preferable that the protective film 12 does not contain at least one nonmetallic element selected from N, O, C, and B. In other words, the total content of N, O, C, and B is preferably 0.1 at % or less. If the total content of N, O, C, and B is 0.1 at % or less, the protective film 12 is more likely to crystallize, while the protective film 12 exhibits favorable resistance to the first etching gas.

In the present embodiment, the protective film 12 is a single-layer film composed of a single layer, but it may also be a multilayer film having a lower layer and an upper layer. The lower layer of the protective film 12 is a layer formed in contact with the uppermost surface of the multilayer reflective film 11. The upper layer of the protective film 12 is in contact with the lowermost surface of the absorbing film 13. In this manner, by forming the protective film 12 into a multilayer structure, materials with excellent predetermined functions can be used in each layer, thereby making the protective film 12 multifunctional as a whole.

The upper layer of the protective film 12 preferably contains at least one metal element selected from Ru and Rh, and more preferably contains Rh. The lower layer of the protective film 12 preferably contains at least one element selected from Ru, Rh, Nb, Mo, Zr, Y, and Si, and more preferably contains Ru. When the protective film 12 is a multilayer film, the thickness of the protective film 12 described below refers to the total film thickness of the multilayer film. It should be noted that a mixing layer formed by mixing components contained in the multilayer reflective film 11 and components contained in the lower layer of the protective film 12 may be formed between the multilayer reflective film 11 and the lower layer of the protective film 12.

The thickness of the protective film 12 is preferably from 1.0 nm to 4.0 nm. If the thickness of the protective film 12 is 1.0 nm or greater, the etching resistance is favorable. Further, when the thickness of the protective film 12 is 4.0 nm or less, the reflectance for EUV light is favorable. The thickness of the protective film 12 is more preferably from 2.0 nm to 3.5 nm, and even more preferably from 2.5 nm to 3.0 nm.

The density of the protective film 12 is preferably from 10.0 g/cm³ to 14.0 g/cm³. If the density of the protective film 12 is 10.0 g/cm³ or more, the etching resistance is favorable. Further, if the density of the protective film 12 is 14.0 g/cm³ or less, absorption of EUV light by the protective film 12 (and therefore a decrease in reflectance for EUV light) can be suppressed.

The method for depositing the protective film 12 is, for example, a DC sputtering method, a magnetron sputtering method, an ion beam sputtering method, or the like. When forming a Ru film using an ion beam sputtering method, an example of the deposition conditions is as follows.

### <Ru Film Deposition Conditions>

Target: Ru target
Sputtering gas: Ar gas
Gas pressure: 0.010 Pa to 0.020 Pa
Target output density: 1.0 W/cm² to 8.5 W/cm²
Deposition rate: 0.01 nm/sec to 0.10 nm/sec
Film thickness: 1 nm to 10 nm.

The absorbing film 13 absorbs EUV light. The absorbing film 13 is a film in which the opening pattern 13op is scheduled to be formed. The opening pattern 13op is not formed in the production process of the reflective mask blank 1, but is formed in the production process of the reflective mask 2. The absorbing film 13 may not only absorb EUV light but also shift the phase of the EUV light. In other words, the absorbing film 13 may be a phase shift film. The phase shift film shifts the phase of the second EUV light L2 relative to the first EUV light L1 shown in FIG. 6.

The first EUV light L1 is light that passes through the opening pattern 13op in the absorbing film 13 without being absorbed by the absorbing film 13, is reflected by the multilayer reflective film 11, and passes through the opening pattern 13op again in the absorbing film 13 without being absorbed by the absorbing film 13. The second EUV light L2 is light that passes through the absorbing film 13 while being absorbed by the absorbing film 13, is reflected by the multilayer reflective film 11, and passes through the absorbing film 13 again while being absorbed by the absorbing film 13.

The phase difference (≥0) between the first EUV light L1 and the second EUV light L2 is, for example, from 1700 to 250°. The phase of the first EUV light L1 may either lead or lag the phase of the second EUV light L2. The absorbing film 13 utilizes interference between the first EUV light L1 and the second EUV light L2 to improve the contrast of the transferred image. The transfer image is an image obtained by transferring the opening pattern 13op in the absorbing film 13 onto the target substrate.

In EUVL, a so-called projection effect (shadowing effect) occurs. The shadowing effect refers to the occurrence of an area, near the side wall of the opening pattern 13op, where the EUV light is blocked by the side wall, due to the incident angle θ of EUV light being not 0° (for example, 6°), resulting in a positional or dimensional deviation of the transferred image. To reduce the shadowing effect, it is effective to lower the height of the side wall of the opening pattern 13op, and thinning the absorbing film 13 is also effective.

To reduce the shadowing effect, the film thickness of the absorbing film 13 is, for example, 60 nm or less, and preferably 50 nm or less. To ensure a phase difference between the first EUV light L1 and the second EUV light L2, the film thickness of the absorbing film 13 is preferably 20 nm or greater, and more preferably 30 nm or greater.

To reduce the film thickness of the absorbing film 13 in order to reduce the shadowing effect while ensuring the phase difference between the first EUV light L1 and the second EUV light L2, it is effective to reduce the refractive index n of the absorbing film 13. Further, to reduce the reflectance for the second EUV light L2, it is effective to increase the extinction coefficient k of the absorbing film 13. As described above, the absorbing film 13 is required to have excellent optical properties.

The absorbing film 13 preferably contains at least one metal element selected from Cr, Ta, Nb, Ir, Pt, Pd, Os, Re, Au, and Ru. Since these metal elements have relatively small refractive indices, the film thickness of the absorbing film 13 can be reduced while ensuring the phase difference. The absorbing film 13 preferably contains a compound of a metal element. The compound of a metal element preferably contains at least one nonmetallic element selected from O, B, C, and N. By adding at least one of these nonmetallic elements, crystallization can be suppressed while suppressing a decrease in optical properties.

The absorbing film 13 more preferably contains Ta as a main component. The absorbing film 13 containing Ta as a main component means that the Ta content in the absorbing film 13 is 50 at % or more. The absorbing film 13 may contain only Ta, but more preferably contains a Ta compound. The Ta compound more preferably contains N in addition to Ta. The inclusion of N in the Ta compound can suppress crystallization of the absorbing film 13. Therefore, the increase in line edge roughness of the opening pattern 13op in the absorbing film 13 due to crystallization of the absorbing film 13 can be suppressed. Further, surface roughness of the absorbing film 13 due to crystallization of the absorbing film 13 can be suppressed, thereby suppressing an increase in the detection rate of pseudo defects. The Ta compound may contain at least one metal element selected from Cr, Nb, Ir, Pt, Pd, Os, Re, Au, and Ru, in addition to Ta.

In the present embodiment, the absorbing film 13 is a single-layer film composed of a single layer, but it may also be a multilayer film having a lower layer and an upper layer. The lower layer and upper layer that make up the absorbing film 13 are formed in this order on the protective film 12. The uppermost layer of the absorbing film 13 is a layer farthest from the protective film 12. The uppermost layer of the absorbing film 13 preferably contains at least one metal element selected from Cr, Ta, Nb, Ir, Pt, Pd, Os, Re, Au, and Ru, and more preferably contains a compound of the metal element. The uppermost layer of the absorbing film 13 more preferably contains Ta as a main component, and even more preferably contains a Ta compound. When the absorbing film 13 is a multilayer film, the thickness of the absorbing film 13 refers to the total film thickness of the multilayer film.

When the Ta compound contains Ta and N, the N atom content of the Ta compound is preferably from 10.0 at % to 35.0 at % in order to increase the etching selectivity, more preferably from 10.0 at % to 25.0 at %, even more preferably from 10.5 at % to 18.0 at %, and particularly preferably from 11.0 at % to 16.0 at %.

When the Ta compound contains N, it may further contain at least one element selected from hafnium (Hf), silicon (Si), zirconium (Zr), titanium (Ti), germanium (Ge), boron (B), tin (Sn), nickel (Ni), cobalt (Co), and hydrogen (H).

The total content of these elements is preferably 10 at % or less.

The method for depositing the absorbing film 13 is, for example, a DC sputtering method, a magnetron sputtering method, an ion beam sputtering method, or the like. The nitrogen content of the absorbing film 13 can be controlled through the N₂ gas content in the sputtering gas.

When forming a TaN film using a reactive sputtering method, an example of the deposition conditions is as follows.

### <TaN Film Deposition Conditions>

Target: Ta target
Ta target output density: 1.0 W/cm² to 8.5 W/cm²
Sputtering gas: mixed gas of Ar gas and N₂ gas
Volume ratio of N₂ gas in sputtering gas (N₂/(Ar+N₂)): 0.01 to 0.25
Gas pressure: 1.0×10⁻² Pa to 1.0×10⁰ Pa
Ta target output density: 1.0 W/cm² to 8.5 W/cm²
Deposition rate: 0.020 nm/sec to 0.060 nm/sec
Film thickness: 20 nm to 60 nm.

The hard mask film 14 is formed on the opposite side of the protective film 12 with reference to the absorbing film 13 and is used to form the opening pattern 13op in the absorbing film 13. The hard mask film 14 enables thinning of the resist film 16.

The hard mask film 14 preferably contains at least one metal element or metalloid element selected from Al, Hf, Y, Cr, Nb, Ti, Mo, Ta, and Si. The hard mask film 14 preferably contains a compound of the above metal element or metalloid element. The compound preferably contains at least one element selected from O, N, C, and B.

The film thickness of the hard mask film 14 is preferably from 2 nm or more and 30 nm or less, more preferably from 2 nm or more and 25 nm or less, and even more preferably from 2 nm or more and 10 nm or less.

The method for depositing the hard mask film 14 is, for example, a DC sputtering method, a magnetron sputtering method, an ion beam sputtering method, or the like.

The conductive film 15 is formed on the opposite side of the multilayer reflective film 11 with reference to the substrate 10, and is used to adsorb the reflective mask 2 to an electrostatic chuck 21 of an exposure device 20. In the present embodiment, the conductive film 15 is a single-layer film composed of a single layer, but it may also be a multilayer film having a lower layer and an upper layer.

From the viewpoints of conductivity and stability, the conductive film 15 preferably contains at least one metal element selected from Cr and Ta. The conductive film 15 preferably contains a compound of the above metal element. The compound preferably contains at least one nonmetallic element selected from N, O, C, B, and Si. The oxygen content of the compound is preferably 30 at % or less.

The film thickness of the conductive film 15 is preferably from 50 nm to 400 nm, and more preferably from 70 nm to 350 nm. When the conductive film 15 is a multilayer film, the film thickness of the conductive film 15 is the total thickness of the multilayer film.

The method for depositing the conductive film 15 is, for example, a DC sputtering method, a magnetron sputtering method, an ion beam sputtering method, or the like.

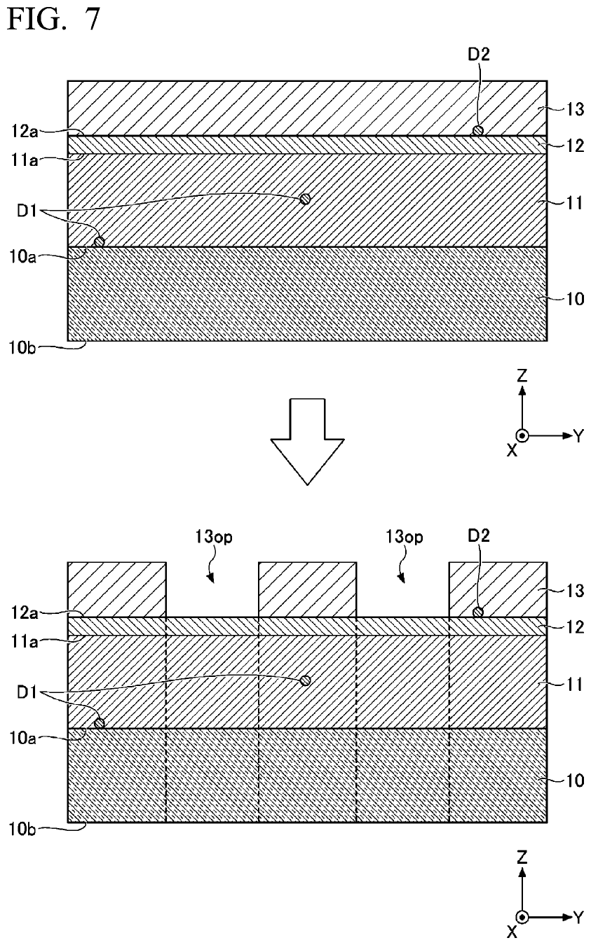

Next, with reference to FIG. 7, an example of the positional relationship between an opening pattern in an absorbing film and defects will be described. As shown in FIG. 7, it is preferable to correct the position of the opening pattern 13op formed in the absorbing film 13 so that defects D1 and D2 present between the substrate 10 and the absorbing film 13 are covered by the absorbing film 13. As a result, the defects D1 and D2 can be made not to adversely affect the EUVL transfer accuracy. This technique is called mitigation. It should be noted that as will be described in more detail later, portions of defects D1 and D2 do not need to be covered by the absorbing film 13.

The defect D1 is a phase defect. A phase defect changes the phase of EUV light by disrupting the layer structure of the multilayer reflective film 11. A phase defect is formed, for example, on the first main surface 10a of the substrate 10 or inside the multilayer reflective film 11. On the other hand, the defect D2 is an amplitude defect. An amplitude defect changes the amplitude of EUV light by absorbing the EUV light. An amplitude defect is formed, for example, on a surface 11a of the multilayer reflective film 11, a surface 12a of the protective film 12 or inside thereof.

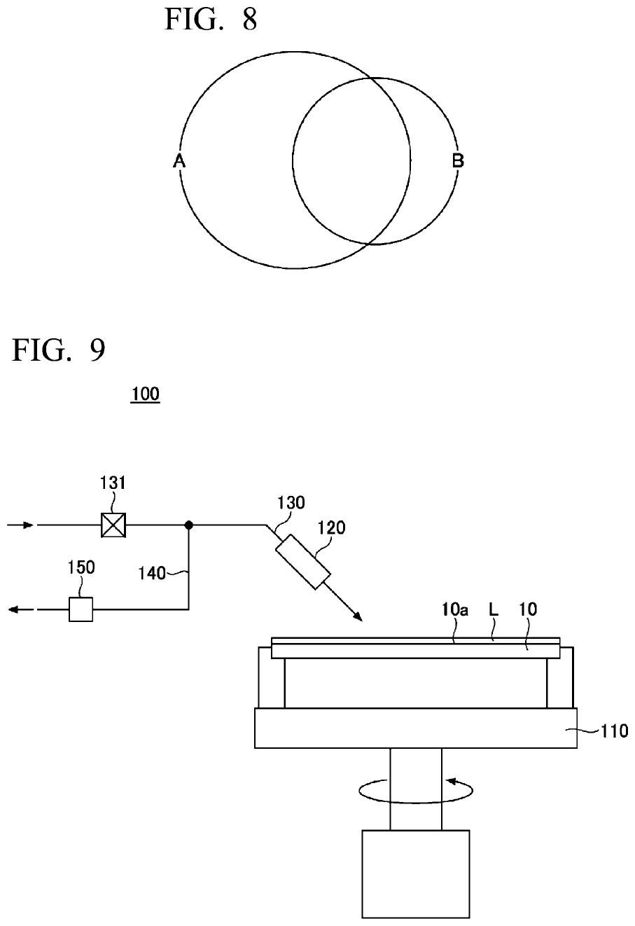

Next, with reference to FIG. 8, an example of the relationship between a set of defects detectable by EUV light and a set of defects detectable by DUV light will be described. In FIG. 8, a set A is a set of defects detectable by EUV light (wavelength: 10 nm to 20 nm), and a set B is a set of defects detectable by DUV light (wavelength: 200 nm to 360 nm). The set A and the set B partially overlap. Whether or not defects are detected as duplicates is determined by whether or not the position coordinates of the defects are the same. When the position coordinates of the defects are the same, they are defects detected as duplicates.

EUV light is suitable for detecting phase defects. On the other hand, DUV light is suitable for detecting amplitude defects. EUV light has a shorter wavelength than DUV light and can detect smaller defects. Therefore, the number of defects belonging to the set A is generally greater than the number of defects belonging to the set B. It should be noted that defects detectable by EUV light may include not only phase defects but also amplitude defects. Further, defects detectable by DUV light may include not only amplitude defects but also phase defects.

Next, with reference to FIG. 9, an example of a spin cleaning device 100 will be described. The spin cleaning device 100 spin-cleans the substrate 10 or various films formed on the substrate 10 (for example, the protective film 12) with pure water L, for example, immediately before or after at least one of steps S102 to S106 shown in FIG. 2. It should be noted that the spin cleaning device 100 may apply ultrasonic waves to the pure water L to improve cleaning efficiency.

The spin cleaning device 100 includes a spin chuck 110 and a nozzle 120. The spin chuck 110 rotates the substrate 10 while holding the substrate 10 horizontally with the first main surface 10a of the substrate 10 facing upward. The nozzle 120 supplies the pure water L to the substrate 10 from above. The pure water L wets and spreads by centrifugal force in the radial direction over the entire substrate 10. In the process, the pure water L sweeps away foreign matter adhered to the substrate 10 or various films radially outward from the substrate 10. After the supply of pure water L is stopped, spin drying is performed.

As will be explained in more detail in the section of Examples, the inventors of the present invention focused on the number of particles with a sphere equivalent diameter of 20 nm or greater per unit volume (1 mL) of pure water L (particles/mL) immediately before the supply of pure water L was stopped. It was discovered in experiments that if this number is 0 particles/mL, the clustering of defects can be suppressed. It is believed that the clustering of defects can be suppressed by cleaning the surface with pure water L containing no particles at the end of the spin cleaning. It should be noted that when the supply of pure water L begins, since particles are generated due to, for example, the operation of an on-off valve 131 described below, the number of particles does not need to be 0 particles/mL.

The spin cleaning device 100 may include a supply line 130, a branch line 140, and a particle counter 150. The supply line 130 supplies the pure water L to the nozzle 120. The on-off valve 131 is provided in the middle of the supply line 130. The branch line 140 branches off from the supply line 130 and sends the pure water L to the particle counter 150. The branch line 140 may branch off from the supply line 130 downstream of the on-off valve 131. The particle counter 150 detects the number of particles with a sphere equivalent diameter of 20 nm or greater per unit volume (1 mL) of pure water L (particles/mL). The sphere equivalent diameter of the particles to be detected is preferably 1,000 nm or less.

While supplying the pure water L from the nozzle 120 to the substrate 10, the spin cleaning device 100 detects the number of particles (particles/mL) contained in the pure water L using the particle counter 150. Then, the spin cleaning device 100 stops the supply of the pure water L after confirming that the number of particles contained in the pure water L has reached 0 particles/mL, and performs spin drying. As a result, it is possible to clean the surface with the pure water L containing no particles at the end of the spin cleaning, and to suppress the clustering of defects. The time from when the number of particles reaches 0 particles/mL to when the supply of the pure water L is stopped is determined based on the time it takes for the pure water L containing no particles to spread over the entire radial direction of the substrate 10, and the like.

In the method for producing the reflective mask blank 1, it is preferable to perform the above-mentioned spin cleaning at the following timing (1). (1) After step S101 (preparation of the substrate) and before step S103 (formation of the multilayer reflective film). By performing the above spin cleaning at the above timing (1), it is possible to suppress the clustering of phase defects.

In the method for producing the reflective mask blank 1, it is preferable to perform the above-mentioned spin cleaning at the following timing (2). (2) After step S104 (formation of the protective film) and before step S105 (formation of the absorbing film). By performing the above spin cleaning at the above timing (2), it is possible to suppress the clustering of amplitude defects.

When the multilayer reflective film 11 and the protective film 12 are formed in a continuous manner using the same film formation equipment, the above spin cleaning is not necessary after step S103 (formation of the multilayer reflective film) and before step S104 (formation of the protective film). However, when the multilayer reflective film 11 and the protective film 12 are formed using different film formation equipment, the above spin cleaning may be performed after step S103 (formation of the multilayer reflective film) and before step S104 (formation of the protective film).

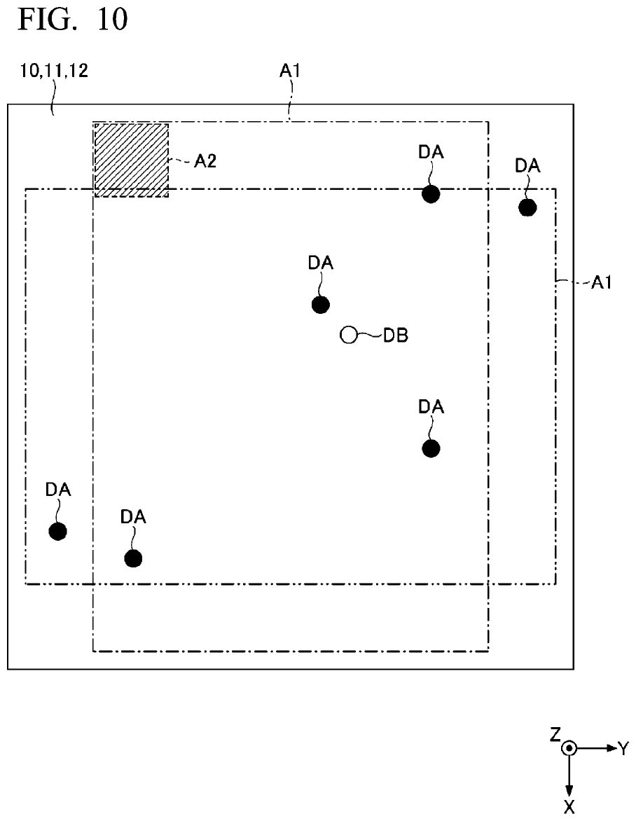

Next, with reference to FIG. 10, a first example of the positional relationship among a quality assurance area A1, an inspection area A2, a first defect DA, and a second defect DB will be described. The protective film 12 has a quality assurance area A1 that coincides with an exposure area in a plan view (viewed in the Z-axis direction). In a plan view, the substrate 10 has, for example, a square shape with each side having a length of 152 mm. In this case, the quality assurance area A1 has, for example, a rectangular shape with a long side having a length of 132 mm and a short side having a length of 104 mm. Each side of the quality assurance area A1 is perpendicular or parallel to each side of the substrate 10. The quality assurance area A1 is set in the center of the protective film 12.

In the present example, the quality assurance area A1 is vertically elongated, as indicated by a one dot chain line, but it may also be horizontally elongated, as indicated by a two dot chain line. The shape of the quality assurance area A1 (that is, vertically elongated or horizontally elongated) can be selected so as to reduce the total number of first defects DA in the quality assurance area A1. The first defect DA is a defect that can be detected by EUV light. In other words, the first defect DA is a defect that belongs to the set A shown in FIG. 8. On the other hand, the second defect DB is a defect that cannot be detected by EUV light but can be detected by DUV light. In other words, the second defect DB is a defect that does not belong to the set A but belongs to the set B shown in FIG. 8. The vertically elongated or horizontally elongated shape may be selected so as to reduce the total number of the first defect DA and the second defect DB.

In the quality assurance area A1 in the present example, after the formation of the protective film 12 and before the formation of the absorbing film 13, at least one of the following conditions (A) to (D) is satisfied in any inspection area A2: (A) The number of first defects DA having a sphere equivalent diameter of 14 nm or greater is 1 or less; (B) The number of first defects DA having a sphere equivalent diameter of 12 nm or greater is 1 or less; (C) The sum of the number of first defects DA having a sphere equivalent diameter of 14 nm or greater and the number of second defects DB having a sphere equivalent diameter of 40 nm or greater is 1 or less; (D) The sum of the number of first defects DA having a sphere equivalent diameter of 12 nm or greater and the number of second defects DB having a sphere equivalent diameter of 40 nm or greater is 1 or less. It should be noted that the sphere equivalent diameter of the first defect DA is preferably 300 nm or less. Further, the sphere equivalent diameter of the second defect DB is preferably 500 nm or less. In the quality assurance area A1, after the formation of the protective film 12 and before the formation of the absorbing film 13, it only needs for at least the above condition (A) to be satisfied in any inspection area A2.

The inspection area A2 in the present example has a square shape with each side having a length of 20 mm. Each side of the inspection area A2 is perpendicular or parallel to each side of the quality assurance area A1. It only needs to continuously shift the inspection area A2 in parallel throughout the entire quality assurance area A1, and to confirm whether or not at least one of the above conditions (A) to (D) is satisfied in any inspection area A2. Here, the positions and numbers of the first defects DA and second defects DB may be inspected after the formation of the protective film 12 and before the formation of the absorbing film. The first defects DA and second defects DB can be present on the first main surface 10a of the substrate 10, on the surface 11a or inside of the multilayer reflective film 11, or on the surface 12a or inside of the protective film 12. If the surface 12a of the protective film 12 is inspected, it is possible to detect the first defects DA and second defects DB not only on the surface 12a of the protective film 12, but also from the surface 12a of the protective film 12 to the first main surface 10a of the substrate 10.

In EUVL, the opening pattern 13op of the absorbing film 13 is transferred onto a semiconductor substrate or the like. The reduction ratio during transfer is generally ¼. Hence, the transferred image of the inspection area A2 has a square shape with each side having a length of 5 mm (20 mm×¼), and has approximately the same size as the semiconductor chip. According to the present example, the number of defects to be concealed by the absorbing film 13 in the fabrication of the circuit pattern of one semiconductor chip can be reduced to 1 or less. Hence, it is possible to improve the success probability for the position correction of the opening pattern 13op formed in the absorbing film 13 so that all target defects are covered by the absorbing film 13.

In the above condition (A), the target defect is the first defect DA having a sphere equivalent diameter of 14 nm or greater. In the above condition (B), the target defect is the first defect DA having a sphere equivalent diameter of 12 nm or greater. In the above condition (C), the target defects are both the first defect DA having a sphere equivalent diameter of 14 nm or greater, and the second defect DB having a sphere equivalent diameter of 40 nm or greater. In the above condition (D), the target defects are both the first defects DA having a sphere equivalent diameter of 12 nm or greater, and the second defects DB having a sphere equivalent diameter of 40 nm or greater.

It should be noted that how the type of the target defect is set, that is, which of the above four conditions (A) to (D) is adopted, may be determined, for example, depending on the required EUVL transfer accuracy; in other words, depending on the circuit pattern of the semiconductor chip. The first defects DA having a sphere equivalent diameter of less than 14 nm have almost no effect on EUVL transfer accuracy. However, depending on the circuit pattern of the semiconductor chip, the first defects DA having a sphere equivalent diameter of 12 nm or greater but less than 14 nm may affect EUVL transfer accuracy. Further, depending on the circuit pattern of the semiconductor chip, the second defects DB having a sphere equivalent diameter of 40 nm or greater may affect EUVL transfer accuracy.

It is more preferable that the following condition (E) is satisfied in the entire quality assurance area A1 after the formation of the protective film 12 and before the formation of the absorbing film 13: (E) The sum of the number of first defects DA having a sphere equivalent diameter of 12 nm or greater and the number of second defects DB having a sphere equivalent diameter of 40 nm or greater is 10 or less. If the above condition (E) is satisfied, it is possible to further improve the success probability for the position correction of the opening pattern 13op formed in the absorbing film 13.

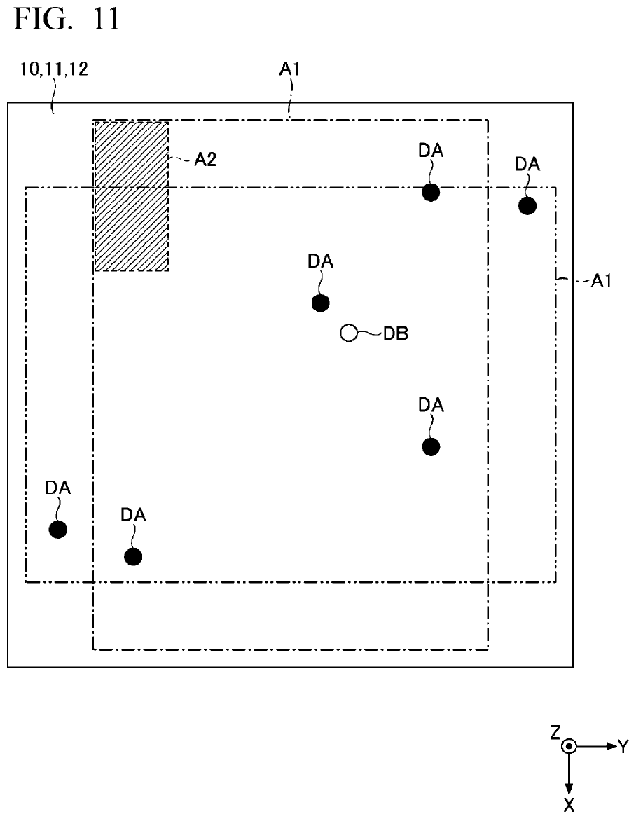

Next, with reference to FIG. 11, a second example of the positional relationships among the quality assurance area A1, the inspection area A2, the first defect DA, and the second defect DB will be described. Hereinafter, differences from the first example shown in FIG. 10 will be mainly described. The inspection area A2 in the present example has a rectangular shape with a long side having a length of 40 mm and a short side having a length of 20 mm. The long sides of the inspection area A2 are parallel to the long sides of the quality assurance area A1. Further, the short side of the inspection area A2 is parallel to the short side of the quality assurance area A1. In the present example, the reduction ratio during transfer in the long side direction is ⅛, and the reduction ratio during transfer in the short side direction is ¼. Therefore, also in the present example, as in the first example, the transferred image of the inspection area A2 has a square shape with each side having a length of 5 mm (20 mm×¼ or 40 mm×⅛), and has approximately the same size as the semiconductor chip. Hence, also in the present example, as in the first example, it only needs for at least one of the above conditions (A) to (D) to be satisfied in any inspection area A2. Further, also in the present example, as in the first example, it is more preferable that the above condition (E) is satisfied in the entire quality assurance area A1.

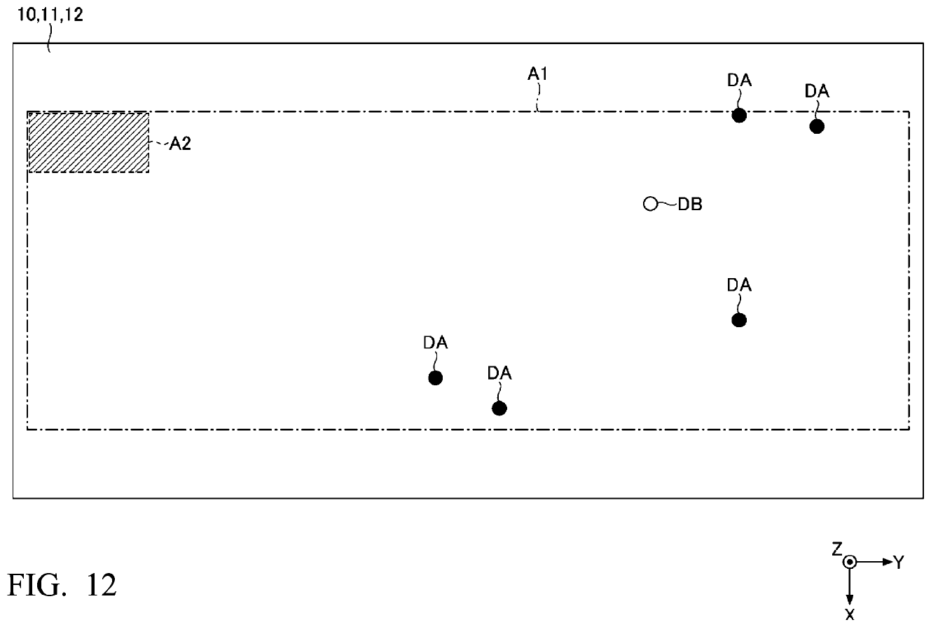

Next, with reference to FIG. 12, a third example of the positional relationship among the quality assurance area A1, the inspection area A2, the first defect DA, and the second defect DB will be described. Hereinafter, differences from the first example shown in FIG. 10 will be mainly described. In a plan view, the substrate 10 has, for example, a rectangular shape with a long side having a length of 304 mm and a short side having a length of 152 mm. In this case, the quality assurance area A1 has, for example, a rectangular shape with a long side having a length of 264 mm and a short side having a length of 104 mm. The inspection area A2 in the present example has a rectangular shape with a long side having a length of 40 mm and a short side having a length of 20 mm. The long sides of the inspection area A2 are parallel to the long sides of the quality assurance area A1. Further, the short side of the inspection area A2 is parallel to the short side of the quality assurance area A1. In the present example, the reduction ratio during transfer in the long side direction is ⅛, and the reduction ratio during transfer in the short side direction is ¼. Therefore, also in the present example, as in the first example, the transferred image of the inspection area A2 has a square shape with each side having a length of 5 mm (20 mm×¼ or 40 mm×⅛), and has approximately the same size as the semiconductor chip. Hence, also in the present example, as in the first example, it only needs for at least one of the above conditions (A) to (D) to be satisfied in any inspection area A2. Further, also in the present example, as in the first example, it is more preferable that the above condition (E) is satisfied in the entire quality assurance area A1.

### EXAMPLES

Experimental data will be described below. In Cases 1 to 5, substrates with a multilayer reflective film were fabricated under the same conditions, except for the cleaning conditions (number of particles immediately before the pure water supply was stopped) shown in Tables 1 and 2. The substrates with a multilayer reflective film included a substrate 10, a multilayer reflective film 11, and a protective film 12. Cases 1 to 2 are Comparative Examples, and Cases 3 to 5 are Examples of the present invention.

A SiO₂—TiO₂-based glass substrate (having an external form of 6-inch (152 mm) square, and a thickness of 6.3 mm) was prepared as the substrate 10. This glass substrate had a thermal expansion coefficient at 20° C. of 0.02×10⁻⁷/° C., a Young's modulus of 67 GPa, a Poisson's ratio of 0.17, and a specific rigidity of 3.07×10⁷ m²/s². A quality assurance area of a first main surface 10a of the substrate 10 had a root mean square roughness (Rq) of 0.15 nm or less and a flatness of 100 nm or less due to polishing.

A Mo/Si multilayer reflective film was formed as the multilayer reflective film 11. The Mo/Si multilayer reflective film was formed by repeatedly depositing a Si layer (film thickness: 4.5 nm) and a Mo layer (film thickness: 2.3 nm) 40 times using an ion beam sputtering method, and then further forming one Si layer (film thickness: 8.0 nm). The total film thickness of the Mo/Si multilayer reflective film was 280 nm ((4.5 nm+2.3 nm)×40+8.0).

A Ru film (film thickness: 2.5 nm) was formed as the protective film 12 using an ion beam sputtering method. It should be noted that in Cases 1 to 5, since the multilayer reflective film 11 and the protective film 12 were formed in a continuous manner using the same film formation equipment, spin cleaning was not performed after the formation of the multilayer reflective film 11 and before the formation of the protective film 12.

After the formation of the protective film 12, the numbers and positions of first defects DA and second defects DB contained in the quality assurance area A1 were investigated. Further, the maximum value for the number of defects contained in the inspection area A2 having a square shape with each side length of 20 mm was determined for each target defect (see Table 1). Moreover, the maximum value for the number of defects contained in the inspection area A2 having a rectangular shape with a long side length of 40 mm and a short side length of 20 mm was determined for each target defect (see Table 2).

Furthermore, the success probability for the position correction of the opening pattern 13op in the absorbing film 13 was determined for each target defect through simulation. More specifically, 10 different opening patterns 13op were prepared, and it was investigated whether or not the positions of the opening patterns 13op could be corrected so that the target defects would not affect the EUVL transfer accuracy. A success probability of 10000 means that for all 10 different opening patterns 13op, the positions of the opening patterns 13op could be corrected so that all of the target defects were hidden by the absorbing film 13.

TABLE 1

| | | | Case 1 | Case 2 | Case 3 | Case 4 | Case 5 |
|---|---|---|---|---|---|---|---|
| Number of particles immediately before supply | | | 5 | 5 | 0 | 0 | 0 |
| of pure water to first main surface of substrate | | | | | | | |
| is stopped [particles/mL] | | | | | | | |
| Number of particles immediately before supply | | | 5 | 5 | 0 | 0 | 5 |
| of pure water to surface of protective film | | | | | | | |
| is stopped [particles/mL] | | | | | | | |
| Number of | Target | First defects | 9 | 5 | 8 | 5 | 8 |
| defects in | defects | (14 nm or greater) | | | | | |
| quality | | First defects | 11 | 6 | 9 | 6 | 9 |
| assurance | | (12 nm or greater) | | | | | |
| area | | Second defects | 1 | 1 | 1 | 1 | 2 |
| [defects] | | (40 nm or greater) | | | | | |
| Maximum | Target | First defects | 2 | 2 | 1 | 1 | 1 |
| value for | defects | (14 nm or greater) | | | | | |
| number of | | First defects | 3 | 2 | 1 | 1 | 1 |
| defects in | | (12 nm or greater) | | | | | |
| inspection | | First defects | 2 | 2 | 1 | 1 | 2 |
| area | | (14 nm or greater), | | | | | |
| [defects/400 | | Second defects | | | | | |
| mm²] | | (40 nm or greater) | | | | | |
| | | First defects | 3 | 2 | 1 | 1 | 2 |
| | | (12 nm or greater), | | | | | |
| | | Second defects | | | | | |
| | | (40 nm or greater) | | | | | |
| Success | Target | First defects | 30 | 40 | 90 | 100 | 90 |
| probability | defects | (14 nm or greater) | | | | | |
| for | | First defects | 20 | 40 | 80 | 100 | 90 |
| position | | (12 nm or greater) | | | | | |
| correction | | First defects | 30 | 40 | 80 | 100 | 30 |
| [%] | | (14 nm or greater), | | | | | |
| | | Second defects | | | | | |
| | | (40 nm or greater) | | | | | |
| | | First defects | 10 | 30 | 70 | 90 | 30 |
| | | (12 nm or greater), | | | | | |
| | | Second defects | | | | | |
| | | (40 nm or greater) | | | | | |

TABLE 2

| | | | Case 1 | Case 2 | Case 3 | Case 4 | Case 5 |
|---|---|---|---|---|---|---|---|
| Number of particles immediately before supply | | | 5 | 5 | 0 | 0 | 0 |
| of pure water to first main surface of substrate | | | | | | | |
| is stopped [particles/mL] | | | | | | | |
| Number of particles immediately before supply | | | 5 | 5 | 0 | 0 | 5 |
| of pure water to surface of protective film | | | | | | | |
| is stopped [particles/mL] | | | | | | | |
| Number of | Target | First defects | 9 | 5 | 8 | 5 | 8 |
| defects in | defects | (14 nm or greater) | | | | | |
| quality | | First defects | 11 | 6 | 9 | 6 | 9 |
| assurance | | (12 nm or greater) | | | | | |
| area | | Second defects | 1 | 1 | 1 | 1 | 2 |
| [defects] | | (40 nm or greater) | | | | | |
| Maximum | Target | First defects | 2 | 2 | 1 | 1 | 1 |
| value for | defects | (14 nm or greater) | | | | | |
| number of | | First defects | 3 | 2 | 1 | 1 | 1 |
| defects in | | (12 nm or greater) | | | | | |
| inspection | | First defects | 2 | 2 | 1 | 1 | 2 |
| area | | (14 nm or greater), | | | | | |
| [defects/800 | | Second defects | | | | | |
| mm²] | | (40 nm or greater) | | | | | |
| | | First defects | 4 | 3 | 2 | 1 | 2 |
| | | (12 nm or greater), | | | | | |
| | | Second defects | | | | | |
| | | (40 nm or greater) | | | | | |
| Success | Target | First defects | 20 | 30 | 80 | 90 | 80 |
| probability | defects | (14 nm or greater) | | | | | |
| for | | First defects | 10 | 30 | 70 | 90 | 80 |
| position | | (12 nm or greater) | | | | | |
| correction | | First defects | 20 | 30 | 70 | 90 | 30 |
| [%] | | (14 nm or greater), | | | | | |
| | | Second defects | | | | | |
| | | (40 nm or greater) | | | | | |
| | | First defects | 0 | 0 | 40 | 80 | 30 |
| | | (12 nm or greater), | | | | | |
| | | Second defects | | | | | |
| | | (40 nm or greater) | | | | | |

Comparing Case 1 and Case 2, it can be seen that the fewer the number of target defects in the entire quality assurance area A1, the higher the success probability for the position correction of the opening pattern 13op in the absorbing film 13. However, in Case 1 and Case 2, since the maximum value for the number of target defects in the inspection area A2 was 2 or more, the success probability for the position correction was 40% or less.

Comparing Case 1 and Case 3, or comparing Case 2 and Case 4, it can be seen that even when the number of target defects in the entire quality assurance area A1 is similar, if the maximum value for the number of target defects in the inspection area A2 is small (in other words, 1 or less), the success probability for the position correction was 70% or higher.

Comparing Case 3 and Case 4, it can be seen that even when the maximum value for the number of target defects in the inspection area A2 is the same (in other words, 1), the fewer the number of target defects in the entire quality assurance area A1, the higher the success probability for the position correction.

In Case 5, when the target defects were both first defects DA and second defects DB, the maximum value for the number of target defects in inspection area A2 exceeded 1, and the success probability for the position correction was low. It is presumed that the large number of second defects DB in Case 5 was due to the number of particles immediately before the supply of pure water to the surface 12a of the protective film 12 was stopped exceeded 0 particles/mL.

Although the reflective mask blank, reflective mask, method for producing a reflective mask blank, and method for producing a reflective mask according to the present disclosure have been described above, the present disclosure is not limited to the above embodiments and the like. Various changes, modifications, substitutions, additions, deletions, and combinations are possible within the scope of the claims. These also naturally fall within the technical scope of the present disclosure.

Priority is claimed on Japanese Patent Application No. 2023-205053, filed Dec. 5, 2023, and Japanese Patent Application No. 2024-018396, filed Feb. 9, 2024, the contents of which are incorporated herein by reference.

### REFERENCE SIGNS LIST

1 Reflective mask blank
2 Reflective mask
10 Substrate
11 Multilayer reflective film
12 Protective film
13 Absorbing film
13op Opening pattern

1. A reflective mask blank comprising, in this order:
a substrate;
a multilayer reflective film that reflects EUV light;
a protective film that protects said multilayer reflective film; and
an absorbing film that absorbs EUV light,
wherein said absorbing film has an exposure area that is scheduled to be exposed to EUV light by an exposure device,
said protective film has a quality assurance area that coincides with said exposure area in a plan view, and
in said quality assurance area, after formation of said protective film and before formation of said absorbing film, the number of first defects detectable by EUV light and having a sphere equivalent diameter of 14 nm or greater is 1 or less in any inspection area having a square shape with each side length of 20 mm.

2. The reflective mask blank according to claim 1,
wherein in said quality assurance area, after formation of said protective film and before formation of said absorbing film, in any of said inspection area, sum of the number of first defects detectable by EUV light and having a sphere equivalent diameter of 14 nm or greater and the number of second defects undetectable by EUV light but detectable by DUV light and having a sphere equivalent diameter of 40 nm or greater is 1 or less.

3. The reflective mask blank according to claim 1,
wherein in said quality assurance area, after formation of said protective film and before formation of said absorbing film, in any of said inspection area, the number of first defects detectable by EUV light and having a sphere equivalent diameter of 12 nm or greater is 1 or less.

4. The reflective mask blank according to claim 3,
wherein in said quality assurance area, after formation of said protective film and before formation of said absorbing film, in any of said inspection area, sum of the number of first defects detectable by EUV light and having a sphere equivalent diameter of 12 nm or greater and the number of second defects undetectable by EUV light but detectable by DUV light and having a sphere equivalent diameter of 40 nm or greater is 1 or less.

5. The reflective mask blank according to claim 4,
wherein throughout said quality assurance area, after formation of said protective film and before formation of said absorbing film, sum of the number of first defects detectable by EUV light and having a sphere equivalent diameter of 12 nm or greater and the number of second defects undetectable by EUV light but detectable by DUV light and having a sphere equivalent diameter of 40 nm or greater is 10 or less.

6. A reflective mask blank comprising, in this order: a substrate; a multilayer reflective film that reflects EUV light; a protective film that protects said multilayer reflective film; and an absorbing film that absorbs EUV light,
wherein said absorbing film has an exposure area that is scheduled to be exposed to EUV light by an exposure device,
said protective film has a quality assurance area that coincides with said exposure area in a plan view,
and in said quality assurance area, after formation of said protective film and before formation of said absorbing film, the number of first defects detectable by EUV light and having a sphere equivalent diameter of 14 nm or greater is 1 or less in any of inspection areas having a rectangular shape with a long side length of 40 mm and a short side length of 20 mm.

7. The reflective mask blank according to claim 6,
wherein in said quality assurance area, after formation of said protective film and before formation of said absorbing film, in any of said inspection area, sum of the number of first defects detectable by EUV light and having a sphere equivalent diameter of 14 nm or greater and the number of second defects undetectable by EUV light but detectable by DUV light and having a sphere equivalent diameter of 40 nm or greater is 1 or less.

8. The reflective mask blank according to claim 6,
wherein in said quality assurance area, after formation of said protective film and before formation of said absorbing film, in any of said inspection area, the number of first defects detectable by EUV light and having a sphere equivalent diameter of 12 nm or greater is 1 or less.

9. The reflective mask blank according to claim 8,
wherein in said quality assurance area, after formation of said protective film and before formation of said absorbing film, in any of said inspection area, sum of the number of first defects detectable by EUV light and having a sphere equivalent diameter of 12 nm or greater and the number of second defects undetectable by EUV light but detectable by DUV light and having a sphere equivalent diameter of 40 nm or greater is 1 or less.

10. The reflective mask blank according to claim 9,
wherein throughout said quality assurance area, after formation of said protective film and before formation of said absorbing film, sum of the number of first defects detectable by EUV light and having a sphere equivalent diameter of 12 nm or greater and the number of second defects undetectable by EUV light but detectable by DUV light and having a sphere equivalent diameter of 40 nm or greater is 10 or less.

11. A reflective mask comprising the reflective mask blank according to claim 1,
wherein an opening pattern is included in said absorbing film.

12. A method for producing a reflective mask blank comprising, in this order, a substrate, a multilayer reflective film that reflects EUV light, a protective film that protects said multilayer reflective film, and an absorbing film that absorbs EUV light, wherein said absorbing film has an exposure area that is scheduled to be exposed to EUV light by an exposure device,
the method comprising:
forming said multilayer reflective film, said protective film, and said absorbing film in this order on a first main surface of said substrate,
wherein said protective film has a quality assurance area that coincides with said exposure area in a plan view, and
in said quality assurance area, after formation of said protective film and before formation of said absorbing film, the number of first defects detectable by EUV light and having a sphere equivalent diameter of 14 nm or greater is 1 or less in any inspection area having a square shape with each side length of 20 mm.

13. A method for producing a reflective mask blank comprising, in this order, a substrate, a multilayer reflective film that reflects EUV light, a protective film that protects said multilayer reflective film, and an absorbing film that absorbs EUV light, wherein said absorbing film has an exposure area that is scheduled to be exposed to EUV light by an exposure device,
the method comprising:
forming said multilayer reflective film, said protective film, and said absorbing film in this order on a first main surface of said substrate,
wherein said protective film has a quality assurance area that coincides with said exposure area in a plan view, and
in said quality assurance area, after formation of said protective film and before formation of said absorbing film, the number of first defects detectable by EUV light and having a sphere equivalent diameter of 14 nm or greater is 1 or less in any of inspection areas having a rectangular shape with a long side length of 40 mm and a short side length of 20 mm.

14. The method for producing a reflective mask blank according to claim 12,
the method comprising:
spin-cleaning said first main surface of said substrate with pure water before forming said multilayer reflective film; and
spin-cleaning a surface of said protective film with pure water after forming said protective film and before forming said absorbing film,
wherein the number of particles having a sphere equivalent diameter of 20 nm or greater per unit volume (1 mL) of said pure water is 0/mL immediately before supply of said pure water to said substrate or said protective film is stopped.

15. A method for producing a reflective mask, comprising, in this order:
preparing the reflective mask blank according to claim 1; and
forming an opening pattern in said absorbing film.

16. A reflective mask comprising the reflective mask blank according to claim 6,
wherein an opening pattern is included in said absorbing film.

17. A method for producing a reflective mask, comprising, in this order:
preparing the reflective mask blank according to claim 6; and
forming an opening pattern in said absorbing film.
